(19) United States
(12) Patent Application Publication
(10) Pub. No.: US 2024/0361693 A1
(43) Pub. Date: Oct. 31, 2024

(54) THINNER COMPOSITION, AND METHOD FOR PRODUCING SEMICONDUCTOR DEVICES USING SAID THINNER COMPOSITION

(71) Applicant: MITSUBISHI GAS CHEMICAL COMPANY, INC., Tokyo (JP)

(72) Inventors: Takumi OKADA, Niigata (JP); Ryosuke HOSHINO, Niigata (JP); Hideyuki SATO, Niigata (JP); Masayuki KATAGIRI, Niigata (JP); Shu SUZUKI, Kanagawa (JP); Masatoshi ECHIGO, Tokyo (JP)

(73) Assignee: MITSUBISHI GAS CHEMICAL COMPANY, INC., Tokyo (JP)

(21) Appl. No.: 18/580,370

(22) PCT Filed: Jul. 25, 2022
(86) PCT No.: PCT/JP2022/028578

§ 371 Date: Jan. 18, 2024

(30) Foreign Application Priority Data
Jul. 30, 2021 (JP) 2021-125387

(51) Int. Cl. G03F 7/105; G03F 7/004; G03F 7/16; H01L 21/02; H01L 21/027

(52) U.S. Cl. CPC G03F 7/105; G03F 7/0048; G03F 7/162; G03F 7/168; H01L 21/02087; H01L 21/0275

(57) ABSTRACT

A thinner composition includes: (B) a solvent containing: (B1) a compound represented by the following general formula (b-1): wherein R1 is an alkyl group having 1 to 10 carbon atoms. A method for manufacturing a semiconductor device includes applying the thinner composition to a substrate, before applying a photoresist film material or a photoresist underlayer film material to the substrate.

### TECHNICAL FIELD

The present invention relates to a thinner composition, and a method for manufacturing a semiconductor device using the thinner composition, and particularly relates to a thinner composition for removing a photoresist film or a photoresist underlayer film.

### BACKGROUND ART

In the manufacture of semiconductor devices and liquid crystal devices, fine processing is performed by lithography involving use a photoresist material. In a lithography process, a photosensitive resin composition is applied to a wafer, a designed pattern is transferred thereon, and then, a fine circuit pattern such as a semiconductor integrated circuit is prepared through an etching process. This is carried out by a method for preparing a fine circuit pattern to be obtained, the method including the application, exposure, development, etching, and stripping processes. In particular, in the manufacture of semiconductor devices, further miniaturization of pattern dimensions has been required along with increases in the integration and speed of LSI, in recent years. To correspond to such miniaturization of pattern dimensions, the light source for lithography used upon forming resist patterns has been shifted from KrF excimer laser (248 nm) to ArF excimer laser (193 nm) and EUV (extreme ultraviolet) light source (13.5 nm), which have a shorter wavelength, so that the fine processing is sensitive to a contaminant source. Accordingly, the residue of the photoresist, BARC, SOC, and SOG applied to a substrate in the application process, and a contamination therewith may serve as contaminant sources in the exposure process, and are therefore required to be removed in advance. In this regard, a thinner composition has been used in an edge bead removing (EBR) process.

In recent years, due to the application of a photoresist or an underlayer film thereof for which a light source having a short wavelength is used, the amount of the photoresist or the underlayer film thereof used have a great influence on the manufacturing cost of the integrated circuit. Thus, it is required to reduce the amount of the photoresist or the underlayer film thereof used to save costs. For this purpose, there has been applied a reducing resist consumption (RRC) process that performs prewetting treatment in which a thinner composition is applied to the surface of a substrate to wet the surface before the application of the photoresist or the underlayer film thereof, thereby allowing the photoresist to be uniformly applied to the entire surface of the substrate even with a small amount of the photoresist or the underlayer film thereof.

Although thinner compositions to be used in various EBR processes and RRC processes have conventionally been developed, a thinner composition that enables those processes to be achieved at a high level has not been developed.

### CITATION LIST

### Patent Literature

Patent Literature 1: Japanese Patent Laid-Open No. 2001-188359
Patent Literature 2: Japanese Patent Laid-Open No. 2005-227770
Patent Literature 3: Japanese Patent Laid-Open No. 2015-232708

### SUMMARY OF INVENTION

### Technical Problem

Thus, as for the thinner composition used in, for example, the EBR process or the RRC process in the manufacture of various devices, there is a need for the development of a thinner composition that can be sufficiently applied to the EBR process for a wide variety of photoresists and underlayer films thereof and has a high RRC efficiency to reduce the manufacturing cost.

### Solution to Problem

The present inventors have intensively studied to solve the above problems, and as a result, have found that the above problems can be solved by a thinner composition which contains a solvent including a compound having a specific structure. That is, the present invention is as follows.

[1] A thinner composition comprising:
(B) a solvent comprising: (B1) a compound represented by the following general formula (b-1).

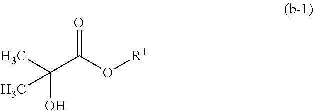

wherein R¹ is an alkyl group having 1 to 10 carbon atoms.
[2] The thinner composition according to the above [1], wherein R¹ in the general formula (b-1) is a methyl group, an ethyl group, an n-propyl group, an i-propyl group, an n-butyl group, an i-butyl group, an s-butyl group, or a t-butyl group.
[3] The thinner composition according to the above [1] or [2], wherein R¹ in the general formula (b-1) is an ethyl group, an n-propyl group, an i-propyl group, an n-butyl group, an i-butyl group, an s-butyl group, or a t-butyl group.
[4] The thinner composition according to any one of the above [1] to [3], wherein the solvent (B) comprises: (B2) a solvent other than the compound (B1).
[5] The thinner composition according to the above [4], wherein the solvent (B) comprises one or more selected from the group consisting of methyl α-methoxyisobutyrate, methyl α-formyloxyisobutyrate, methyl α-acetyloxyisobutyrate, and methyl 3-hydroxyisobutyrate, as the solvent (B2).
[6] The thinner composition according to the above [4] or [5], wherein the solvent (B2) is contained in an amount less than 100% by mass, based on the total amount (100% by mass) of the thinner composition.
[7] The thinner composition according to the above [4] or [5], wherein the solvent (B2) is contained in an amount of 100% by mass or less based on the total amount (100% by mass) of the compound (B1).
[8] The thinner composition according to the above [4] or [5], wherein the solvent (B2) is contained in an amount less than 112.5% by mass based on the total amount (100% by mass) of the compound (B1).
[9] The thinner composition according to any one of the above [4] to [8], wherein the solvent (B2) is contained in an amount of 0.0001% by mass or more based on the total amount (100% by mass) of the compound (B1).
[10] A method for manufacturing a semiconductor device, comprising:
a step of applying the thinner composition according to any one of the above [1] to [9] to a substrate before applying a photoresist film material or a photoresist underlayer film material to the substrate.
   [11] A method for manufacturing a semiconductor device, comprising:
a step of applying the thinner composition according to any one of the above [1] to [9] to a substrate, after applying a photoresist film material or a photoresist underlayer film material to the substrate and before an exposure step.
   [12] A method for manufacturing a semiconductor device comprising:
a step of forming a photoresist film or a photoresist underlayer film on a substrate, and
a step of removing the photoresist film or the photoresist underlayer film by using the thinner composition according to any one of the above [1] to [9].
   [13] The method for manufacturing a semiconductor device according to the above [12], wherein the photoresist film or the photoresist underlayer film is removed by bringing the thinner composition into contact with an edge and/or a back surface of the substrate on which the photoresist film or the photoresist underlayer film is formed.
   [14] The method for manufacturing a semiconductor device according to the above [13], wherein the photoresist film or the photoresist underlayer film is removed by spraying the thinner composition to the edge and/or the back surface of the substrate on which the photoresist film or the photoresist underlayer film is formed, while rotating the substrate.
   [15] The method for manufacturing a semiconductor device according to any one of the above [12] to [14], further comprising a step of drying the thinner composition remained on the substrate, after the step of removing the photoresist film or the photoresist underlayer film.
   [16] The method for manufacturing a semiconductor device according to any one of the above [12] to [15], further comprising:
a step of soft baking the photoresist film,
a step of partially exposing the soft baked photoresist film to light via a mask, and
a step of developing the exposed photoresist film with a developer to form a photoresist pattern.
   [17] The method for manufacturing a semiconductor device according to any one of the above [12] to [16], wherein in a case where the photoresist film or the photoresist underlayer film is formed on an edge and/or a back surface of the substrate, the method further comprises a step of removing the photoresist film or the photoresist underlayer film on the edge and/or the back surface of the substrate after the photoresist film or the photoresist underlayer film is formed on the substrate.
   [18] A solvent composition comprising: (B) a solvent comprising (B1) a compound represented by the following general formula (b-1), and (B2) a solvent other than the compound (B1):

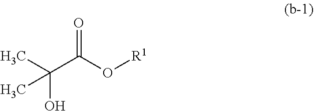

wherein R¹ is an alkyl group having 1 to 10 carbon atoms.
   [19] The solvent composition according to the above [18], wherein the solvent (B) comprises one or more selected from the group consisting of methyl α-methoxyisobutyrate, methyl α-formyloxyisobutyrate, methyl α-acetyloxyisobutyrate, and methyl 3-hydroxyisobutyrate, as the solvent (B2).
   [20] The solvent composition according to the above [18] or [19], wherein the solvent (B2) is contained in an amount less than 112.5% by mass based on the total amount (100% by mass) of the compound (B1).
   [21] The solvent composition according to any one of the above [18] to [20], wherein the solvent (B2) is contained in an amount of 0.0001% by mass or more based on the total amount (100% by mass) of the compound (B1).
   [22] A prewetting liquid comprising the thinner composition according to any one of the above [1] to [9].
   [23] An edge bead removing liquid comprising the thinner composition according to any one of the above [1] to [9].
   [24] A rework liquid comprising the thinner composition according to any one of the above [1] to [9].

### Advantageous Effects of Invention

The thinner composition of a suitable aspect of the present invention enables suitable treatment of substrates for the manufacture of various devices (in particular, semiconductor devices) and removal of a photoresist or an underlayer film thereof.

### BRIEF DESCRIPTION OF DRAWINGS

FIG. 1 is a photograph upon evaluation of rework performance using the thinner composition of Example A5-1a.

FIG. 2 is a photograph upon evaluation of rework performance using the thinner composition of Comparative Example A5-1b.

### DESCRIPTION OF EMBODIMENTS

### [Thinner Composition]

The thinner composition of the present invention contains: (B) a solvent containing: (B1) a compound represented by the general formula (b-1) (hereinafter, also referred to as the “component (B)”).

### <Component (B): Solvent>

The thinner composition of one aspect of the present invention contains: (B) a solvent containing: (B1) a compound represented by the following general formula (b-1).

The compound (B1) may be used singly or in combination of two or more thereof.

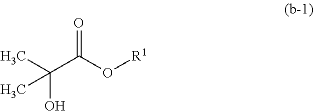

In the above formula (b-1), R¹ is an alkyl group having 1 to 10 carbon atoms. The alkyl group may be a linear alkyl group or a branched alkyl group.

Examples of the alkyl group capable of being selected as R¹ include a methyl group, an ethyl group, an n-propyl group, an i-propyl group, an n-butyl group, an i-butyl group, an s-butyl group, or a t-butyl group, a pentyl group, a hexyl group, a heptyl group, an octyl group, a 2-ethylhexyl group, a nonyl group, and a decyl group.

Among these, R¹ in the general formula (b-1) is preferably a methyl group, an ethyl group, an n-propyl group, an i-propyl group, an n-butyl group, an i-butyl group, an s-butyl group, or a t-butyl group, in one aspect of the present invention, more preferably an ethyl group, an n-propyl group, an i-propyl group, an n-butyl group, an i-butyl group, an s-butyl group, or a t-butyl group, further preferably an n-propyl group, an i-propyl group, an n-butyl group, an i-butyl group, an s-butyl group, or a t-butyl group, and further more preferably an i-propyl group, an n-butyl group, or an i-butyl group.

In the thinner composition of one aspect of the present invention, (B2) a solvent other than the compound (B1) may be contained as the component (B).

Examples of the solvent (B2) include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; compounds having an ester bond such as ethylene glycol monoacetate, diethylene glycol monoacetate, propylene glycol monoacetate, and dipropylene glycol monoacetate; compounds having an ether bond, such as mono alkyl ethers such as monomethyl ether, monoethyl ether, monopropyl ether, and monobutyl ether or monophenyl ethers of the polyhydric alcohol or the compounds having an ester bond; cyclic ethers such as dioxane, and esters other than the compound (B1), such as methyl lactate, ethyl lactate, methyl acetate, ethyl acetate, butyl acetate, methyl pyruvate, ethyl pyruvate, methyl α-methoxyisobutyrate, methyl f-methoxyisobutyrate, ethyl 2-ethoxyisobutyrate, methyl methoxypropionate, ethyl ethoxypropionate, methyl α-formyloxyisobutyrate, and methyl β-formyl oxyisobutyrate; aromatic organic solvents such as anisole, ethylbenzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene; and dimethylsulfoxide (DMSO).

These solvents (B2) may be used singly or in combination of two or more thereof.

However, in the thinner composition of the present invention, the content of the compound (B1) in the component (B) is preferably 20 to 100% by mass, more preferably 30 to 100% by mass, further preferably 50 to 100% by mass, further more preferably 60 to 100% by mass, and particularly preferably 70 to 100% by mass, based on the total amount (100% by mass) of the component (B) contained in the thinner composition, in view of achieving not only an EBR process but also an RRC process at the same time.

The component (B) used in one aspect of the present invention preferably contains one or more selected from the group consisting of methyl α-methoxyisobutyrate, methyl α-formyloxyisobutyrate, methyl α-acetyloxyisobutyrate, and methyl 3-hydroxyisobutyrate, as the solvent (B2), in view of excellent solubility of an acid generating agent, EBR performance and rework performance, excellent in-plane uniformity of a coating film obtained upon use as a prewetting liquid, and improving the production yield of a semiconductor device. It is preferable to contain methyl α-methoxyisobutyrate, in view of the solubility of the resin, that is, removability. It is preferable to contain methyl α-formyloxyisobutyrate or methyl α-acetyloxyisobutyrate, in view of excellent solubility of the resin, EBR performance and rework performance, a small contact angle, and RRC performance. It is preferable to contain methyl 3-hydroxyisobutyrate, in view of a small contact angle and RRC performance. The method for mixing methyl α-methoxyisobutyrate, methyl α-formyloxyisobutyrate, methyl α-acetyloxyisobutyrate, or methyl 3-hydroxyisobutyrate is not particularly limited, and they can be contained by either a method including adding methyl α-methoxyisobutyrate, methyl α-formyloxyisobutyrate, methyl α-acetyloxyisobutyrate, or methyl 3-hydroxyisobutyrate to the compound (B1), or a method including mixing the component (B) by forming any of them as a by-product or incorporating any of them in the manufacturing process of the compound (B1).

The content of the solvent (B2) is not limited, and is less than 112.5% by mass, and preferably less than 100% by mass, or 70% by mass or less, in view of improving productivity by shortening the drying time of the thinner composition. The content of the solvent (B2) is more preferably 60% by mass or less, 50% by mass or less, 40% by mass or less, 30% by mass or less, 20% by mass or less, 10% by mass or less, 5% by mass or less, or 1% by mass or less, in view of increasing the solvency of the solvent while ensuring a moderate drying time, and further preferably 0.1% by mass or less, and particularly preferably 0.01% by mass or less, based on the total amount (100% by mass) of the compound (B1). The content of the solvent (B2) is preferably 0.0001% by mass or more, more preferably 0.001% by mass or more, and further preferably 0.01% by mass or more, in view of excellent in-plane uniformity of a coating film obtained upon use as a prewetting liquid and improving the production yield of a semiconductor device. On the other hand, the content of the solvent (B2) is preferably more than 125% by mass, based on the total amount (100% by mass) of the compound (B1), in view of applicability at high temperature conditions.

The content of methyl α-methoxyisobutyrate, methyl α-formyloxyisobutyrate, methyl α-acetyloxyisobutyrate, or methyl 3-hydroxyisobutyrate is not particularly limited, and is preferably less than 100% by mass, more preferably 70% by mass or less, 60% by mass or less, 50% by mass or less, 40% by mass or less, 30% by mass or less, 20% by mass or less, 10% by mass or less, 5% by mass or less, and 1% by mass or less, further preferably 0.1% by mass or less, and particularly preferably 0.01% by mass or less, based on the total amount (100% by mass) of the thinner composition, in view of shortening the drying time of the thinner composition to improve productivity. The content thereof is preferably 0.0001% by mass or more, more preferably 0.001% by mass or more, and further preferably 0.01% by mass or more, in view of excellent in-plane uniformity of a coating film obtained upon use as a prewetting liquid and improving the production yield of a semiconductor device.

The content of methyl α-methoxyisobutyrate, methyl α-formyloxyisobutyrate, methyl α-acetyloxyisobutyrate, or methyl 3-hydroxyisobutyrate is less than 112.5% by mass, preferably 100% by mass or less, and more preferably 70% by mass or less, 60% by mass or less, 50% by mass or less, 40% by mass or less, 30% by mass or less, 20% by mass or less, 10% by mass or less, 5% by mass or less, or 1% by mass or less, further preferably 0.1% by mass or less, and particularly preferably 0.01% by mass or less, based on the total amount (100% by mass) of the compound (B1), in view of improving productivity by shortening the drying time of the thinner composition. The content thereof is preferably 0.0001% by mass or more, more preferably 0.001% by mass or more, and further preferably 0.01% by mass or more, in view of excellent in-plane uniformity of a coating film obtained upon use as a prewetting liquid and improving the production yield of a semiconductor device. On the other hand, the content thereof is preferably more than 125% by mass, based on the total amount (100% by mass) of the compound (B1), in view of applicability at high temperature conditions.

The component (B) used in one aspect of the present invention preferably contains one or more selected from the group consisting of methyl α-formyloxyisobutyrate, methyl α-acetyloxyisobutyrate, and methyl 3-hydroxyisobutyrate, as the solvent (B2).

In the thinner composition of the present invention, the content of the component (B) may be appropriately set depending on the application, and may be 50% by mass or more, 54% by mass or more, 58% by mass or more, 60% by mass or more, 65% by mass or more, 69% by mass or more, 74% by mass or more, 77% by mass or more, 80% by mass or more, 82% by mass or more, 84% by mass or more, 88% by mass or more, 90% by mass or more, 94% by mass or more, or 97% by mass or more, based on the total amount (100% by mass) of the thinner composition.

The upper limit value of the content of the component (B) may be appropriately set, and the content may be 99% by mass or less, 98% by mass or less, 96% by mass or less, 93% by mass or less, 91% by mass or less, 86% by mass or less, 81% by mass or less, 76% by mass or less, 71% by mass or less, 66% by mass or less, or 61% by mass or less, based on the total amount (100% by mass) of the thinner composition.

The range of the content of the component (B) can be specified by any combination of an upper limit value and a lower limit value appropriately selected from the options each mentioned above.

The thinner composition of the present invention may contain other components other than the above component (B), depending on the application. Examples of other components include one or more selected from the group consisting of a surfactant and an antioxidant. Each content of these other components is appropriately selected depending on the type of the component, and is preferably 0.000000001 to 1 part by mass, more preferably 0.000001 to 0.1 parts by mass, and further preferably 0.00001 to 0.001 parts by mass, per 1 part by mass of the component (B) contained in the thinner composition.

As the surfactant used in one aspect of the present invention, one known in the art can be used without particular limitation. Preferred examples thereof include ethylene glycol methyl ether, ethylene glycol dimethyl ether, ethylene glycol ethyl ether, ethylene glycol methyl ethyl ether, ethylene glycol diethyl ether, diethylene glycol methyl ether, diethylene glycol dimethyl ether, diethylene glycol ethyl ether, diethylene glycol methyl ethyl ether, diethylene glycol diethyl ether, diethylene glycol propyl ether, diethylene glycol methyl propyl ether, diethylene glycol ethyl propyl ether, and diethylene glycol dipropyl ether. These can be each used singly, or as a mixture of two or more thereof.

As the antioxidant used in one aspect of the present invention, one known in the art can be used without particular limitation, and examples thereof include a tocopherol antioxidant, a phenol antioxidant, a hindered amine antioxidant, a phosphorus antioxidant, a sulfur antioxidant, a benzotriazole antioxidant, a benzophenone antioxidant, a hydroxylamine antioxidant, a salicylic acid ester antioxidant, and a triazine antioxidant.

### Tocopherol Antioxidant

A tocopherol compound is typically vitamin E, and is also a naturally derived chemical substance. Thus, the tocopherol compound is highly safety and low in environmental load. In addition, the tocopherol compound is oil-soluble and liquid at ambient temperature, and is thus excellent in compatibility with the thinner composition and the like, and also excellent in deposition resistance.

Examples of the tocopherol compound include tocopherol and a derivative thereof, and tocotrienol and a derivative thereof. Tocopherol and tocotrienol are known to have a distinction such as a natural type compound (d-form), a non-natural type compound (1-form), and a racemate (dl-form) which is an equivalent mixture thereof. Some natural type compounds (d-form) and racemates (dl-form) are used as a food additive, for example, and are thus preferable.

Specific examples of tocopherol include d-α-tocopherol, dl-α-tocopherol, d-β-tocopherol, dl-β-tocopherol, d-γ-tocopherol, dl-γ-tocopherol, d-δ-tocopherol, and dl-δ-tocopherol.

Specific examples of tocotrienol include d-α-tocotrienol, dl-α-tocotrienol, d-β-tocotrienol, dl-β-tocotrienol, d-γ-tocotrienol, dl-γ-tocotrienol, d-δ-tocotrienol, and dl-δ-tocotrienol.

Specific examples of the tocopherol derivative include acetic acid esters, nicotinic acid esters, linoleic acid esters, and succinic acid esters of the above tocopherols. Specific examples of the tocotrienol derivative include acetic acid esters of the above tocotrienols.

### Phenol Antioxidant

Examples of the phenol antioxidant include hindered phenol antioxidants. Examples of the hindered phenol antioxidant include 2,4-bis[(laurylthio)methyl]-o-cresol, 1,3,5-tris(3,5-di-t-butyl-4-hydroxybenzyl), 1,3,5-tris(4-t-butyl-3-hydroxy-2,6-dimethylbenzyl), 2,4-bis-(n-octylthio)-6-(4-hydroxy-3,5-di-t-butylanilino)-1,3,5-triazine, pentaerythritol tetrakis[3-(3,5-di-tert-butyl-4-hydroxyphenyl)propionate], 2,6-di-t-butyl-4-nonylphenol, 2,2′-isobutylidene-bis-(4,6-dimethyl-phenol), 4,4′-butylidene-bis-(2-t-butyl-5-methylphenol), 2,2′-thio-bis-(6-t-butyl-4-methylphenol), 2,5-di-t-amyl-hydroquinone, 2,2′-thiodiethylbis-(3,5-di-t-butyl-4-hydroxyphenyl)-propionate, 1,1,3-tris-(2′-methyl-4′-hydroxy-5′-t-butylphenyl)-butane, 2,2′-methylene-bis-(6-(1-methyl-cyclohexyl)-p-cresol), 2,4-dimethyl-6-(1-methyl-cyclohexyl)-phenol, N,N-hexamethylenebis(3,5-di-t-butyl-4-hydroxy-hydrocinnamamide), 4,4′-butylidenebis-(6-t-butyl-3-methylphenol), 2,2′-methylenebis-(4-ethyl-6-t-butylphenol), and butylhydroxyanisole. Moreover, oligomer-type and polymer-type compounds having a hindered phenol structure can also be used.

Other examples of the phenol antioxidant include dibutylhydroxytoluene (BHT) and hydroquinone, in addition to the aforementioned hindered phenol antioxidants.

### Hindered Amine Antioxidant

Examples of the hindered amine antioxidant include bis(2,2,6,6-tetramethyl-4-piperidyl) sebacate, bis(N-methyl-2,2,6,6-tetramethyl-4-piperidyl) sebacate, N,N′-bis(2,2,6,6-tetramethyl-4-piperidyl)-1,6-hexamethylene diamine, 2-methyl-2-(2,2,6,6-tetramethyl-4-piperidyl)amino-N-(2,2,6,6-tetramethyl-4-piperidyl)propionamide, tetrakis(2,2,6,6-tetramethyl-4-piperidyl) butane 1,2,3,4-tetracarboxylate, poly[{6-(1,1,3,3-tetramethylbutyl)imino-1,3,5-triazine-2,4-diyl}{(2,2,6,6-tetramethyl-4-piperidyl)imino}hexamethyl{(2,2,6,6-tetramethyl-4-piperidyl)imino}], poly[(6-morpholino-1,3,5-triazine-2,4-diyl){(2,2,6,6-tetramethyl-4-piperidyl)imino}hexamethine{(2,2,6,6-tetramethyl-4-piperidyl)imino}], a polycondensate of dimethyl succinate and 1-(2-hydroxyethyl)-4-hydroxy-2,2,6,6-tetramethylpiperidine, and N,N′-4,7-tetrakis[4,6-bis{N-butyl-N-(1,2,2,6,6-pentamethyl-4-piperidyl)amino}-1,3,5-triazin-2-yl]-4,7-diazadecane-1,10-diamine. Moreover, oligomer-type and polymer-type compounds having a hindered amine structure can also be used.

### Phosphorus Antioxidant

Examples of the phosphorus antioxidant include tris(isodecyl) phosphite, tris(tridecyl) phosphite, phenyl isooctyl phosphite, phenyl isodecyl phosphite, phenyl di(tridecyl) phosphite, diphenyl isooctyl phosphite, diphenyl isodecyl phosphite, diphenyl tridecyl phosphite, triphenyl phosphite, tris(nonylphenyl) phosphite, 4,4′-isopropylidene diphenol alkylphosphite, trisnonylphenyl phosphite, trisdinonylphenyl phosphite, tris(2,4-di-t-butylphenyl) phosphite, tris(biphenyl) phosphite, distearyl pentaerythritol diphosphite, di(2,4-di-t-butylphenyl)pentaerythritol diphosphite, di(nonylphenyl)pentaerythritol diphosphite, phenylbisphenol A pentaerythritol diphosphite, tetratridecyl 4,4′-butylidenebis(3-methyl-6-t-butylphenol) diphosphite, hexatridecyl 1,1,3-tris(2-methyl-4-hydroxy-5-t-butylphenyl)butane triphosphite, 3,5-di-t-butyl-4-hydroxybenzyl phosphite diethyl ester, sodiumbis(4-t-butylphenyl) phosphite, sodium-2,2-methylene-bis(4,6-di-t-butylphenyl)-phosphite, 1,3-bis(diphenoxyphosphonyloxy)-benzene, tris(2-ethylhexyl) phosphite, triisodecyl phosphite, and ethylbis(2,4-ditert-butyl-6-methylphenyl) phosphite. Moreover, oligomer-type and polymer-type compounds having a phosphite structure can also be used.

### Sulfur Antioxidant

Examples of the sulfur antioxidant include 2,2-thio-diethylenebis[3-(3,5-di-t-butyl-4-hydroxyphenyl)propionate], 2,4-bis[(octylthio)methyl]-o-cresol, 2,4-bis[(laurylthio)methyl]-o-cresol, didodecyl 3,3′-thiodipropionate, dioctadecyl 3,3′-thiodipropionate, and ditetradecyl 3,3′thiodipropionate. Moreover, oligomer-type and polymer-type compounds having a thioether structure can also be used.

### Benzotriazole Antioxidant

As the benzotriazole antioxidant, oligomer-type and polymer-type compounds having a benzotriazole structure can be used.

### Benzophenone Antioxidant

Examples of the benzophenone antioxidant include 2-hydroxy-4-methoxybenzophenone, 2,4-dihydroxybenzophenone, 2-hydroxy-4-n-octoxybenzophenone, 4-dodecyloxy-2-hydroxybenzophenone, 2-hydroxy-4-octadecyloxybenzophenone, 2,2′dihydroxy-4-methoxybenzophenone, 2,2′dihydroxy-4,4′-dimethoxybenzophenone, 2,2′,4,4′-tetrahydroxybenzophenone, 2-hydroxy-4-methoxy-5-sulfobenzophenone, 2-hydroxy-4-methoxy-2′-carboxybenzophenone, and 2-hydroxy-4-chlorobenzophenone. Moreover, oligomer-type and polymer-type compounds having a benzophenone structure can also be used.

### Hydroxylamine Antioxidant

Examples of the hydroxylamine antioxidant include hydroxylamine, hydroxylamine nitrate, hydroxylamine sulfate, hydroxylamine phosphate, hydroxylamine hydrochloride, hydroxylamine citrate, and hydroxylamine oxalate.

### Salicylic Acid Ester Antioxidant

Examples of the salicylic acid ester antioxidant include phenyl salicylate, p-octylphenyl salicylate, and p-tertbutylphenyl salicylate. Moreover, oligomer-type and polymer-type compounds having a salicylic acid ester structure can also be used.

### Triazine Antioxidant

Examples of the triazine antioxidant include 2,4-bis(allyl)-6-(2-hydroxyphenyl)1,3,5-triazine. Moreover, oligomer-type and polymer-type compounds having a triazine structure can also be used.

Such a thinner composition of the present invention has excellent dissolving power for various photoresist films, photoresist underlayer films (films applied to the underlayer of a photoresist, such as a bottom antireflection coating (BARC) and a spin-on-carbon film) and photoresist upper layer films (top antireflection coating (TARC)), whereby the thinner composition of the present invention may improve EBR characteristics, rework characteristics, and application performance of the photoresist film, the photoresist underlayer film, and the photoresist upper layer film, and furthermore, is excellent in RRC characteristics. In particular, in the case of the respective photoresists for g-line, i-line, KrF, ArF, EUV, and EB, the basic structures of these photoresists are different from each other. Although the formulation and content of the organic solvent is required to be controlled to improve the dissolving power and application properties for all of them, the thinner composition of the present invention satisfies such a requirement.

### <Method for Manufacturing Semiconductor Device>

One embodiment of the present invention is a method for manufacturing a semiconductor device, the method involving use of the thinner composition according to the present invention.

More specifically, one embodiment of the present invention is a method for manufacturing a semiconductor device, the method including a step of applying the above thinner composition of the present invention to a substrate, before applying a photoresist film material, a photoresist upper layer film material, or a photoresist underlayer film material to the substrate.

Another embodiment of the present invention is a method for manufacturing a semiconductor device, the method including a step of applying the above thinner composition of the present invention to a substrate, after applying a photoresist film material or a photoresist underlayer film material to the substrate and before an exposure step.

Still another embodiment of the present invention is a method for manufacturing a semiconductor device, the method including a step of forming a photoresist film or a photoresist underlayer film on a substrate, and a step of removing the photoresist film or the photoresist underlayer film by using the above thinner composition of the present invention.

In the embodiment, a mode is preferable in which the photoresist film or the photoresist underlayer film is removed by bringing the thinner composition into contact with an edge and/or a back surface of the substrate on which the photoresist film or the photoresist underlayer film is formed.

In the embodiment, another mode is also preferable in which the photoresist film or the photoresist underlayer film is removed by spraying the thinner composition to the edge and/or the back surface of the substrate on which the photoresist film or the photoresist underlayer film is formed, while rotating the substrate.

Still another mode is also preferable in which the method further includes a step of drying the thinner composition remained on the substrate, after the step of removing the photoresist film or the photoresist underlayer film.

Yet another mode is also preferable in which the method further includes a step of soft baking the photoresist film, a step of partially exposing the soft baked photoresist film to light via a mask, and a step of developing the exposed photoresist film with a developer to form a photoresist pattern.

Further, in a case where the photoresist film or the photoresist underlayer film is formed on the edge and/or the back surface of the substrate, yet another mode is also preferable in which the method further includes a step of removing the photoresist film or the photoresist underlayer film on the edge and/or the back surface of the substrate after the photoresist film or the photoresist underlayer film is formed on the substrate.

When the photoresist or the photoresist underlayer film is applied after treating the substrate with the thinner composition, the substrate can be coated with a small amount of the photoresist or the photoresist underlayer film, so that process cost and productivity are improved.

The method for manufacturing a semiconductor device of the present invention can include a step of treating the substrate with the thinner composition, then applying a photoresist or a photoresist underlayer film, and before an exposure step, further treating the substrate with the thinner composition.

By further treating the substrate with the thinner composition in the above step, the unnecessary photoresist or photoresist underlayer film applied to the periphery or rear surface of the substrate can be quickly and effectively removed before the exposure step.

### EXAMPLES

Hereinafter, the present invention will be described by way of Examples, but the present invention is not limited by these Examples in any way. The measurement values in Examples were found by using the following method or apparatus.

### (1) Content of Constitutional Unit of Resin

The content of the constitutional unit of a resin was measured by performing 1024 scans in the quantitative mode of ¹³C using ¹³C-NMR (model name “JNM-ECA500”, manufactured by JEOL Ltd., 125 MHz) with heavy chloroform as a solvent.

### (2) Weight Average Molecular Weight (Mw), Number Average Molecular Weight (Mn), and Molecular Weight Distribution (Mw/Mn) of Resin

Mw and Mn of the resin were measured, in terms of polystyrene as a standard, by gel permeation chromatography (GPC) under the following conditions.
Apparatus name: LaChrom series manufactured by Hitachi, Ltd.
Detector: RI detector L-2490
Column: two TSKgel GMHHR-M columns+guard column HHR-H manufactured by Tosoh Corporation
Solvent: THE (with a stabilizer)
Flow rate: 1 mL/min
Column temperature: 40° C.

Then, the ratio of the calculated Mw to Mn [Mw/Mn] of the resin was calculated as the value of the molecular weight distribution of the resin.

The solvents used in the following Examples and Comparative Examples were as follows.

### <Component (B1)>

HBM: methyl 2-hydroxyisobutyrate, a compound in which R¹ is a methyl group in the general formula (b-1).
iPHIB: isopropyl 2-hydroxyisobutyrate, a compound in which R¹ is an i-propyl group in the general formula (b-1).
iBHIB: isobutyl 2-hydroxyisobutyrate, a compound in which R¹ is an i-butyl group in the general formula (b-1).
nBHIB: n-butyl 2-hydroxyisobutyrate, a compound in which R¹ is an n-butyl group in the general formula (b-1).

### <Component (B2)>

PGMEA: propylene glycol monomethyl ether acetate

The resins used in the following Examples and Comparative Examples are as follows.

### Synthetic Examples 1 to 6 (Synthesis of Resins (i) to (vi))

### (1) Monomer as Starting Material

In the synthesis of the resins (i) to (vi), the following monomers as starting materials were used. The structure of each monomer as the starting material is as shown in Table 1.
EADM: 2-ethyl-2-adamantyl methacrylate
MADM: 2-methyl-2-adamantyl methacrylate
NML: 2-methacryloxy-4-oxatricyclo[4.2.1.0^{3,7}]nonan-5-one
GBLM: α-methacryloxy-γ-butyrolactone
HADM: 3-hydroxy-1-adamantyl methacrylate

TABLE 1

| Monomer | | | | | |
|---|---|---|---|---|---|
| as starting | | | | | |
| material | EADM | MADM | NML | GBLM | HADM |
| Compound | 2-Ethyl-2-adamantyl | 2-Methyl-2-adamantyl | 2-Methacloyloxy-4- | α-Methacloyloxy-γ- | 3-Hydroxy-1-adamantyl |
| name | methacrylate | methacrylate | oxatricyclo-[4.2.1.0^{3,7}]nonan-5-one | butyrolactone | methacrylate |
| Structure | 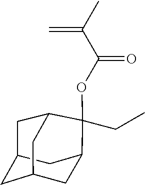 [SMILES: C=C(C)C(=O)OC1(CC)C2CC3CC(C2)CC1C3] | 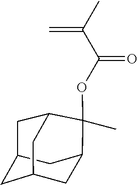 [SMILES: C=C(C)C(=O)OC1(C)C2CC3CC(C2)CC1C3] | 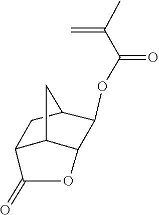 [SMILES: C=C(C)C(=O)OC1C2CC3C(=O)OC1C3C2] | 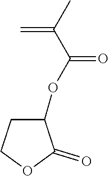 | 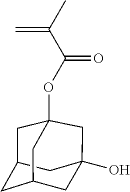 [SMILES: C=C(C)C(=O)OC12CC3CC(CC(O)(C3)C1)C2] |

### (2) Synthesis of Resins (i) to (vi)

In a 300 mL round bottomed flask, 10 g in total of the monomers as starting materials were blended according to the kind and the blending ratio described in Table 2, and 300 g of tetrahydrofuran (manufactured by Wako Pure Chemical Industries, Ltd., guaranteed reagent, free from stabilizer) was further added, followed by stirring. Then, the mixture was degassed for 30 minutes in a nitrogen stream. After degassing, 0.95 g of 2,2′-azobis(isobutyronitrile) (manufactured by Tokyo Kasei Kogyo Co., Ltd., reagent) was added, and a polymerization reaction was conducted at 60° C. in a nitrogen stream so as to obtain a resin having a desired molecular weight.

After the completion of the reaction, the reaction solution cooled to room temperature (25° C.) was added dropwise to a large excess amount of hexane to precipitate a polymerization product. The precipitated polymerization product was collected by filtering, and the obtained solid was washed with methanol and then dried under reduced pressure at 50° C. for 24 hours to obtain each of the intended ArF resins (i) to (vi).

The content of each constitutional unit, and the Mw, Mn, and Mw/Mn of the obtained resins (i) to (vi) were measured and calculated based on the aforementioned measurement method. The results are shown in Table 2.

TABLE 2

| | Formulation of monomers as | | | | | | | | | | | | | |
|---|---|---|---|---|---|---|---|---|---|---|---|---|---|---|
| Acrylic | starting materials (molar ratio) | | | | | Content of constitutional unit of resin (mol %) | | | | | | Molecular weight of resin | | |
| resin | EADM | MADM | NML | GBLM | HADM | EADM | MADM | NML | GBLM | HADM | Total | Mw | Mn | Mw/Mn |
| Resin (i) | 40 | | 40 | | 20 | 32.8 | | 38.3 | | 28.9 | 100 | 5940 | 3260 | 1.82 |
| Resin (ii) | 40 | | | 40 | 20 | 30.7 | | | 43.9 | 25.4 | 100 | 9850 | 4820 | 2.04 |
| Resin (iii) | | 40 | 40 | | 20 | | 38.0 | 37.7 | | 24.3 | 100 | 6480 | 3160 | 2.05 |
| Resin (iv) | | 40 | | 40 | 20 | | 23.7 | | 44.9 | 31.4 | 100 | 15800 | 6820 | 2.32 |
| Resin (v) | | 40 | 40 | | 20 | | 41.6 | 33.0 | | 25.4 | 100 | 14200 | 7260 | 1.96 |
| Resin (vi) | | 40 | | 60 | | | 25.4 | | 74.6 | | 100 | 11500 | 3770 | 3.05 |

The resins (vii) to (viii) are as follows.
Resin (vii): cresol novolac resin (EP4080) (manufactured by ASAHI YUKIZAI CORPORATION)
Resin (viii): a copolymer having a constitutional unit of hydroxystyrene/t-butylacrylate=2/1 (molar ratio) (MARUKA LYNCUR) (manufactured by Maruzen Petrochemical Co., Ltd.)

The acid generating agents used in Examples and Comparative Examples are as follows.
Acid generating agent (i): WPAG336 (manufactured by FUJIFILM Wako Pure Chemical Corporation)
Acid generating agent (ii): WPAG367 (manufactured by FUJIFILM Wako Pure Chemical Corporation)
Acid generating agent (iii): triphenylsulfonium nonafluorobutanesulfonate (manufactured by Sigma-Aldrich)
Acid generating agent (iv): TPS-C1 (manufactured by Heraeus)
Acid generating agent (v): TPS-N3 (manufactured by Heraeus)
Acid generating agent (vi): DTBPIO-C1 (manufactured by Heraeus)
Acid generating agent (vii): MDT (manufactured by Heraeus)

### [Evaluation of Dissolving Power]

### Examples 1a to 17a, 1b to 13b, Comparative Examples 1a to 8a, 1b to 7b

The evaluation of dissolving power for the resins (i) to (viii) and the acid generating agents (i) to (vii) shown in Table 3 to Table 6 was performed for methyl 2-hydroxyisobutyrate (HBM), isopropyl 2-hydroxyisobutyrate (iPHIB), isobutyl 2-hydroxyisobutyrate (iBHIB), or n-butyl 2-hydroxyisobutyrate (nBHIB) as the solvents in Examples, and propylene glycol monomethyl ether acetate (PGMEA) as the solvent in Comparative Examples.

Each of the resins (i) to (viii) was put in each solvent so that the resin concentration was 15 wt %, and the state after stirring at room temperature for 24 hours was visually evaluated according to the following criteria.
Rank A: Dissolved (clear solution was visually observed)
Rank C: Insoluble (cloudy solution was visually observed)

Each of the acid generating agents (i) to (vii) was put in each solvent so that the acid generating agent concentration was 10 wt %, and the state after stirring at room temperature for 1 hour was visually evaluated according to the following criteria.
Rank A: Dissolved (clear solution was visually observed)
Rank C: Insoluble (cloudy solution was visually observed)

The results are shown in Table 3 to Table 6.

TABLE 3

| | Resin | Resin | Resin | Resin | Resin | Resin | Resin | Resin |
|---|---|---|---|---|---|---|---|---|
| | (i) | (ii) | (iii) | (iv) | (v) | (vi) | (vii) | (viii) |
| Example | 1a | 2a | 3a | 4a | 5a | 6a | 7a | 8a |
| HBM | A | A | A | A | A | A | A | A |
| Comparative | 1a | 2a | 3a | 4a | 5a | 6a | 7a | 8a |
| Example | | | | | | | | |
| PGMEA | A | A | A | A | C | C | A | A |

TABLE 4

| | Resin | Resin | Resin | Resin | Resin | Resin | Resin | Resin | Resin |
|---|---|---|---|---|---|---|---|---|---|
| | (i) | (i) | (i) | (v) | (v) | (v) | (viii) | (viii) | (viii) |
| Example | 9a | 10a | 11a | 12a | 13a | 14a | 15a | 16a | 17a |
| iPHIB | A | | | A | | | A | | |
| iBHIB | | A | | | A | | | A | |
| nBHIB | | | A | | | A | | | A |
| Comparative | 1a | 1a | 1a | 5a | 5a | 5a | 8a | 8a | 8a |
| Example | | | | | | | | | |
| PGMEA | A | A | A | C | C | C | A | A | A |

TABLE 5

| | Acid | Acid | Acid | Acid | Acid | Acid | Acid |
|---|---|---|---|---|---|---|---|
| | generating | generating | generating | generating | generating | generating | generating |
| | agent | agent | agent | agent | agent | agent | agent |
| | (i) | (ii) | (iii) | (iv) | (v) | (vi) | (vii) |
| Example | 1b | 2b | 3b | 4b | 5b | 6b | 7b |
| HBM | A | A | A | A | A | A | A |
| Comparative | 1b | 2b | 3b | 4b | 5b | 6b | 7b |
| Example | | | | | | | |
| PGMEA | C | C | A | A | A | A | A |

TABLE 6

| | Acid | Acid | Acid | Acid | Acid | Acid |
|---|---|---|---|---|---|---|
| | gener- | gener- | gener- | gener- | gener- | gener- |
| | ating | ating | ating | ating | ating | ating |
| | agent | agent | agent | agent | agent | agent |
| | (i) | (i) | (i) | (iii) | (iii) | (iii) |
| Example | 8b | 9b | 10b | 11b | 12b | 13b |
| iPHIB | A | | | A | | |
| iBHIB | | A | | | A | |
| nBHIB | | | A | | | A |
| Comparative | 1b | 1b | 1b | 3b | 3b | 3b |
| Example | | | | | | |
| PGMEA | C | C | C | A | A | A |

When the thinner compositions of the present invention were used, the solubility of the resins (i) to (viii) and the acid generating agents (i) to (vii) was excellent, and in particular, it is demonstrated that the thinner compositions of the present invention were useful as the thinner composition for EBR applications and rework applications. On the other hand, when the thinner compositions of Comparative Examples were used with respect to the solubility of the resins (i) to (viii) and the acid generating agents (i) to (vii), some were found to be insoluble, and it was demonstrated that the thinner compositions of Comparative Examples was not useful as the thinner composition.

Thus, when the thinner composition that satisfies the requirement of the present embodiment is used, good solubility can be provided as compared with the thinner compositions of Comparative Examples, which do not satisfy the requirement. Also, thinner compositions other than those described in Examples exhibit the same effect, as long as the above requirement of the present embodiment is satisfied.

### [Evaluation of Solubility]

Using each solvent shown in Table 7, each of the thinner compositions of Examples A1-1 to A1-4 and Comparative Example A1-1 was prepared. In addition, using each solvent shown in Table 8, each of the thinner compositions of Examples A2-1a to A2-4 and Comparative Example A2-1 was prepared. Then, the evaluation of dissolving power of these thinner composition was performed for the resins (i) to (v) and the acid generating agents (i) to (iv) shown in Table 7 and Table 8.

### <Solvent>

HBM: methyl 2-hydroxyisobutyrate (manufactured by Mitsubishi Gas Chemical Company, Inc.)
αMBM: methyl α-methoxyisobutyrate (synthesized with reference to “US2014/0275016”)
αFBM: methyl α-formyloxyisobutyrate (synthesized with reference to “WO2020/004467”)
αABM: methyl α-acetyloxyisobutyrate (synthesized with reference to “WO2020/004466”)
3HBM: methyl 3-hydroxyisobutyrate (manufactured by Tokyo Kasei Kogyo Co., Ltd.)
iPHIB: isopropyl 2-hydroxyisobutyrate (manufactured by Mitsubishi Gas Chemical Company, Inc.)

### <Resin>

The resins having the following compositional ratios (molecular weight) were synthesized by the above methods.
(i) EADM/NML=18/82 (Mn=3750)
(ii) MADM/NML=25/75 (Mn=2740)
(iii) MADM/GBLM=25/75 (Mn=3770)
(iv) MADM/NML/HADM=42/33/25 (Mn=7260)
(v) a copolymer having constitutional units of hydroxystyrene/t-butyl acrylate/styrene=3/1/1 (molar ratio) (manufactured by Maruzen Petrochemical Co., Ltd., Mw=12,000)

### <Acid Generating Agent>

(i) WPAG-336 (manufactured by FUJIFILM Wako Pure Chemical Corporation)
(ii) WPAG-367 (manufactured by FUJIFILM Wako Pure Chemical Corporation)
(iii) WPAG-145 (manufactured by FUJIFILM Wako Pure Chemical Corporation)
(iv) triphenylsulfonium trifluoro-1-butanesulfonate (Sigma-Aldrich)

Each resin of the kind shown in Table 7 was added to each thinner composition shown in Table 7 such that the resin concentration was 15 wt %, and each acid generating agent of the kind shown in Table 7 was added to the mixture such that the acid generating agent concentration was 1 wt %. The state after stirring at room temperature for 24 hours was visually evaluated according to the following criteria.
Rank S: Dissolved (clear solution was visually found)
Rank A: Almost dissolved (almost clear solution was visually found)
Rank C: Insoluble (cloudy solution was visually found)

Each resin shown in Table 8 was added to each thinner composition shown in Table 8 such that the resin concentration was 40 wt %, and each acid generating agent of the kind shown in Table 8 was added to the mixture such that the acid generating agent concentration was a predetermined concentration. The state after stirring at room temperature for 1 hour was visually evaluated according to the following criteria.
Rank S: 5 wt % Dissolved (clear solution was visually found)
Rank A: 1 wt % Dissolved (clear solution was visually found)
Rank C: 1 wt % Insoluble (cloudy solution was visually found)

The results are shown in Table 7 and Table 8.

TABLE 7

| | | Resin | Resin | Resin | Resin |
|---|---|---|---|---|---|
| | | (i) | (ii) | (iii) | (iv) |
| | | Acid | Acid | Acid | Acid |
| | | genera- | genera- | genera- | genera- |
| | | ting | ting | ting | ting |
| | | agent | agent | agent | agent |
| | Solvent | (iv) | (iv) | (iv) | (iv) |
| Example A1-1 | HBM/αMBM | A | A | S | S |
| | (1:1 weight ratio) | | | | |
| Example A1-2 | HBM/αFBM | S | S | S | S |
| | (1:1 weight ratio) | | | | |
| Example A1-3 | HBM/3HBM | A | A | S | S |
| | (1:1 weight ratio) | | | | |
| Example A1-4 | HBM | A | A | S | S |
| Comparative | PGMEA | C | C | C | C |
| Example A1-1 | | | | | |

TABLE 8

| | | Resin | Resin | Resin |
|---|---|---|---|---|
| | | (v) | (v) | (v) |
| | | Acid | Acid | Acid |
| | | genera- | genera- | genera- |
| | | ting | ting | ting |
| | | agent | agent | agent |
| | Solvent | (i) | (ii) | (iii) |
| Example A2-1a | HBM/αMBM | S | S | S |
| | (1:1 weight ratio) | | | |
| Example A2-1b | HBM/αMBM | S | S | S |
| | (9:1 weight ratio) | | | |
| Example A2-1c | HBM/αMBM | S | S | S |
| | (1:0.001 weight ratio) | | | |
| Example A2-1d | HBM/αMBM | S | S | S |
| | (1:0.00005 weight ratio) | | | |
| Example A2-2a | HBM/αFBM | S | S | S |
| | (1:1 weight ratio) | | | |
| Example A2-2b | HBM/αFBM | S | S | S |
| | (9:1 weight ratio) | | | |
| Example A2-2c | HBM/αFBM | S | S | S |
| | (1:0.001 weight ratio) | | | |
| Example A2-2d | HBM/αFBM | S | S | S |
| | (1:0.00005 weight ratio) | | | |
| Example A2-3a | HBM/3HBM | S | S | S |
| | (1:1 weight ratio) | | | |
| Example A2-3b | HBM/3HBM | S | S | S |
| | (9:1 weight ratio) | | | |
| Example A2-3c | HBM/3HBM | S | S | S |
| | (1:0.001 weight ratio) | | | |
| Example A2-3d | HBM/3HBM | S | S | S |
| | (1:0.00005 weight ratio) | | | |
| Example A2-4 | HBM | S | S | A |
| Comparative | PGMEA | A | C | A |
| Example A2-1 | | | | |

It is found from Table 7 that the thinner compositions prepared in Examples A1-1 to A1-4 are excellent in the solubility of the resin as compared with the thinner composition of Comparative Example A1-1. In particular, the thinner compositions in which the solvent (B) contains αFBM as the solvent (B2) exhibit high solubility of any of the resins and are suitably used.

It is found from Table 8 that the thinner compositions prepared in Examples A2-1a to A2-4 are excellent in the solubility of any acid generating agents as compared with the thinner composition of Comparative Example A2-1. In particular, the thinner compositions in which the solvent (B) contains αMBM, αFBM, or 3HBM as the solvent (B2) exhibit high solubility of any acid generating agents and are suitably used.

### [Evaluation of Contact Angle]

### (Preparation of Thinner Composition)

Each thinner composition was prepared according to the formulation shown in Table 9.

Moreover, a solution of 34.0 wt % of a copolymer having a constitutional unit of hydroxystyrene/t-butylacrylate/styrene=3/1/1 (molar ratio) (manufactured by Maruzen Petrochemical Co., Ltd., Mw=12,000) in PGMEA/PGME=8/2 (weight ratio) was prepared as a resist solution (provided that, 500 ppm of a surfactant was added to the copolymer). Here, PGMEA is propylene glycol monomethyl ether acetate, and PGME is propylene glycol monomethyl ether.

Then, 2 mL of each thinner composition prepared above was dropped on a Si wafer in a booth having a controlled constant temperature and humidity of 23° C. and 45% RH, and applied by spin coating at 1000 rpm for 3 seconds. Thereafter, the wafer was transferred to the stage of a contact angle meter, 10 μL of a droplet of the resist solution was put on the center of the wafer with the tip of a syringe needle made of Teflon, and the contact angle after 1 second was evaluated.

### Contact Angle:

Rank A: less than 100
Rank B: 10° or more and less than 17°
Rank C: 170 or more

TABLE 9

| | | Contact |
|---|---|---|
| | | angle |
| Example A3-1a | HBM/αMBM | B |
| | (1:1 weight ratio) | |
| Example A3-1b | HBM/αMBM | B |
| | (9:1 weight ratio) | |
| Example A3-2a | HBM/αFBM | A |
| | (1:1 weight ratio) | |
| Example A3-2b | HBM/αFBM | A |
| | (9:1 weight ratio) | |
| Example A3-3a | HBM/3HBM | A |
| | (1:1 weight ratio) | |
| Example A3-3b | HBM/3HBM | A |
| | (9:1 weight ratio) | |
| Example A3-4 | HBM | B |
| Comparative Example | PGMEA | C |
| A3-1a | | |
| Comparative Example | PGMEA/PGME | C |
| A3-1b | (3:7 weight ratio) | |

As shown in Table 9, the thinner compositions prepared in Examples A3-1a to A3-4 have a small contact angle, whereby the thinner compositions are uniformly applied as the prewetting liquid to the entire substrate surface even with only a small amount of a photoresist or an underlayer film thereof, and are suitably used in the RRC process as compared with the thinner compositions of Comparative Examples A3-1a to A3-1b. Namely, when the thinner composition of the present invention is used as the prewetting liquid, the contact angle upon subsequent addition of the photoresist composition or the underlayer film composition thereof becomes small. As a result, the entire substrate surface can be uniformly coated with a smaller amount of the photoresist composition or the underlayer film composition (referred to as the RRC process). In particular, the thinner compositions in which the solvent (B) contains αFBM or 3HBM as the solvent (B2) have a smaller contact angle, so that the entire substrate surface is coated even with only a smaller amount of the photoresist or the underlayer film thereof, and such thinner compositions are more suitably used.

### [Evaluation of In-Plane Uniformity]

### (Preparation of Thinner Composition)

Each thinner composition was prepared according to the formulation shown in Table 10.

Moreover, a solution of 34.0 wt % of a copolymer having a constitutional unit of hydroxystyrene/t-butylacrylate/styrene=3/1/1 (molar ratio) (manufactured by Maruzen Petrochemical Co., Ltd., Mw=12,000) in PGMEA/PGME=8/2 (weight ratio) was prepared as a resist solution.

Then, 1.1 mL of each thinner composition prepared above was dropped on a Si wafer, and applied by spin coating at 1000 rpm for 0.5 seconds. Thereafter, addition of 1.6 mL of the resist solution was started at 0.3 mL/second, and applied by spin coating at 200 rpm for 2 seconds, at 3000 rpm for 3 seconds, at 200 rpm for 1 second, and at 1200 rpm for 60 seconds, and the in-plane uniformity of the obtained resist film was evaluated.

In-plane uniformity was evaluated by measuring the thicknesses at 25 points in total from the center of the wafer at an interval of 3 mm excluding 3 mm from the edge, and determining 3σ of them.

### In-Plane Uniformity:

Rank A: less than 2.0%
Rank B: 2.0% or more and less than 2.5%
Rank C: 2.5% or more

TABLE 10

| | | In-plane |
|---|---|---|
| | | uniformity |
| Example A4-1a | HBM/αMBM | A |
| | (1:0.1 weight ratio) | |
| Example A4-1b | HBM/αMBM | A |
| | (1:0.001 weight ratio) | |
| Example A4-1c | HBM/αMBM | A |
| | (1:0.00005 weight ratio) | |
| Example A4-2a | HBM/αFBM | A |
| | (1:0.1 weight ratio) | |
| Example A4-2b | HBM/αFBM | A |
| | (1:0.001 weight ratio) | |
| Example A4-2c | HBM/αFBM | A |
| | (1:0.00005 weight ratio) | |
| Example A4-3a | HBM/3HBM | A |
| | (1:0.1 weight ratio) | |
| Example A4-3b | HBM/3HBM | A |
| | (1:0.001 weight ratio) | |
| Example A4-3c | HBM/3HBM | A |
| | (1:0.00005 weight ratio) | |
| Example A4-4a | HBM/αABM | A |
| | (1:0.1 weight ratio) | |
| Example A4-4b | HBM/αABM | A |
| | (1:0.001 weight ratio) | |
| Example A4-4c | HBM/αABM | A |
| | (1:0.00005 weight ratio) | |
| Example A4-5 | HBM | B |

As shown in Table 10, the thinner compositions prepared in Examples A4-1a to A4-5 enable formation of a good resist film having small in-plane uniformity, and are suitably used as the prewetting liquid in the RRC process. In particular, the thinner compositions in which the solvent (B) contains αMBM, αFBM, αABM, or 3HBM as the solvent (B2) enable formation of a good resist film having smaller in-plane uniformity, and are thus more suitably used.

### [Evaluation of Reworkability]

The reworkability for the photoresist film was tested with the thinner compositions of Examples and Comparative Examples described in Table 12 below. The photoresist of the resin (ii) described in Table 2 was applied to a 6-inch silicone substrate so as to have a film thickness of 180 nm. The wafer after the finish of a soft baking step was subjected to a rework step by the method as in Table 11 below with each thinner composition.

The reworked silicone substrate was visually evaluated according to the following evaluation criteria. The results are shown in Table 12 below.

### <Evaluation Criteria>

A: No streak of a photoresist residue was found
B: A streak of a photoresist residue was found

TABLE 11

| | | | Thinner composition |
|---|---|---|---|
| Step | Time (sec) | Rotation speed (rpm) | dispense (mL) |
| 1 | 2 | 0 | 0 |
| 2 | 2 | 1000 | 0 |
| 3 | 4 | 1000 | 2 |
| 4 | 9.5 | 4000 | 0 |

TABLE 12

| | | Reworkability |
|---|---|---|
| Example A5-1a | HBM/αMBM | A |
| | (1:0.1 weight ratio) | |
| Example A5-1b | HBM/αMBM | A |
| | (1:0.001 weight ratio) | |
| Example A5-1c | HBM/αMBM | A |
| | (1:0.00005 weight ratio) | |
| Example A5-2a | HBM/αFBM | A |
| | (1:0.1 weight ratio) | |
| Example A5-2b | HBM/αFBM | A |
| | (1:0.001 weight ratio) | |
| Example A5-2c | HBM/αFBM | A |
| | (1:0.00005 weight ratio) | |
| Example A5-3a | HBM/3HBM | A |
| | (1:0.1 weight ratio) | |
| Example A5-3b | HBM/3HBM | A |
| | (1:0.001 weight ratio) | |
| Example A5-3c | HBM/3HBM | A |
| | (1:0.00005 weight ratio) | |
| Example A5-4a | HBM/αABM | A |
| | (1:0.1 weight ratio) | |
| Example A5-4b | HBM/αABM | A |
| | (1:0.001 weight ratio) | |
| Example A5-4c | HBM/αABM | A |
| | (1:0.00005 weight ratio) | |
| Example A5-5 | HBM | B |
| Comparative Example | PGMEA | B |
| A5-1a | | |
| Comparative Example | PGMEA/PGME | B |
| A5-1b | (3:7 weight ratio) | |

From the results of Table 12, it was demonstrated that the thinner composition of the present invention was excellent in rework performance. Thus, the thinner composition of the present invention is useful to be used as the rework liquid.

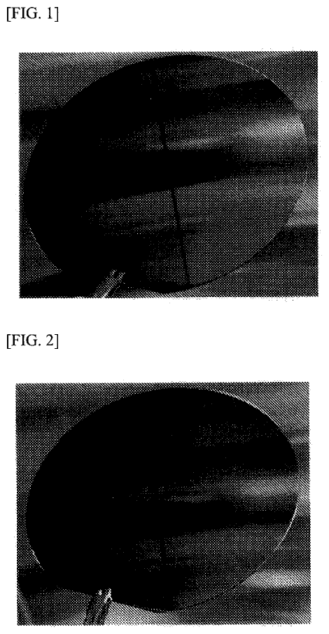

Respective photographs upon evaluation of rework performance with each of the thinner compositions of Example A5-1a and Comparative Example A5-1b were shown in FIG. 1 and FIG. 2.

### [Evaluation of EBR Property]

The photoresist of the resin (ii) described in Table 2 was applied to a 6-inch silicone substrate so as to have a film thickness of 180 nm, and then the thinner compositions of Examples and Comparative Examples described in Table 13 below were subjected to an edge bead removing (EBR) experiment in which the unnecessary resist film at the edge portion was removed. Each thinner composition of Examples and Comparative Examples was discharged from an EBR nozzle at a flow rate of 0.5 mL/sec. The rotation speed of the substrate was 2000 rpm, and the release time of the thinner composition was 20 sec. Then, the removal performance for the unnecessary photosensitive film was evaluated using an optical microscope according to the following evaluation criteria, and the results are shown in Table 13 below.

### <Evaluation Criteria>

A: Uniformity (line uniformity) of the EBR line with respect to the photosensitive film is constant after EBR
B: The shape of the edge portion after EBR is in a distorted state due to the solvent action of thinner

TABLE 13

| | | EBR |
|---|---|---|
| | | property |
| Example A6-1a | HBM/αMBM | A |
| | (1:0.1 weight ratio) | |
| Example A6-1b | HBM/αMBM | A |
| | (1:0.001 weight ratio) | |
| Example A6-1c | HBM/αMBM | A |
| | (1:0.00005 weight ratio) | |
| Example A6-2a | HBM/αFBM | A |
| | (1:0.1 weight ratio) | |
| Example A6-2b | HBM/αFBM | A |
| | (1:0.001 weight ratio) | |
| Example A6-2c | HBM/αFBM | A |
| | (1:0.00005 weight ratio) | |
| Example A6-3a | HBM/3HBM | A |
| | (1:0.1 weight ratio) | |
| Example A6-3b | HBM/3HBM | A |
| | (1:0.001 weight ratio) | |
| Example A6-3c | HBM/3HBM | A |
| | (1:0.00005 weight ratio) | |
| Example A6-4a | HBM/αABM | A |
| | (1:0.1 weight ratio) | |
| Example A6-4b | HBM/αABM | A |
| | (1:0.001 weight ratio) | |
| Example A6-4c | HBM/αABM | A |
| | (1:0.00005 weight ratio) | |
| Example A6-5 | HBM | B |
| Comparative Example | PGMEA | B |
| A6-1a | | |
| Comparative Example | PGMEA/PGME | B |
| A6-1b | (3:7 weight ratio) | |

From the results of Table 13, it was demonstrated that the thinner composition of the present invention was excellent in EBR performance. Thus, the thinner composition of the present invention is useful to be used as the edge bead removing liquid.

The thinner composition of the present invention has excellent dissolving power for various photoresist films, photoresist underlayer films (films applied to the underlayer of a photoresist, such as a bottom antireflection coating (BARC) and a spin-on-carbon film) and photoresist upper layer films (top antireflection coating (TARC)), whereby the thinner composition of the present invention may improve EBR characteristics, rework characteristics, and application performance of the photoresist film, the photoresist underlayer film, and the photoresist upper layer film, and furthermore, is excellent in RRC characteristics. In particular, in the case of the respective photoresists for g-line, i-line, KrF, ArF, EUV, and EB, the basic structures of the photoresist are different from each other. Although the formulation and content of the organic solvent is required to be controlled to improve the dissolving power and application properties for all of them, the thinner composition of the present invention satisfies such a requirement. Also, thinner compositions other than those described in Examples exhibit the same effect, as long as the above requirement of the present embodiment is satisfied.

1. A thinner composition comprising:
(B) a solvent comprising: (B1) a compound represented by the following general formula (b-1): 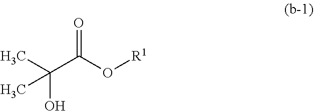
wherein R¹ is an alkyl group having 1 to 10 carbon atoms.

2. The thinner composition according to claim 1, wherein R¹ in the general formula (b-1) is a methyl group, an ethyl group, an n-propyl group, an i-propyl group, an n-butyl group, an i-butyl group, an s-butyl group, or a t-butyl group.

3. The thinner composition according to claim 1, wherein R¹ in the general formula (b-1) is an ethyl group, an n-propyl group, an i-propyl group, an n-butyl group, an i-butyl group, an s-butyl group, or a t-butyl group.

4. The thinner composition according to claim 1, wherein the solvent (B) comprises: (B2) a solvent other than the compound (B1).

5. The thinner composition according to claim 4, wherein the solvent (B) comprises one or more selected from the group consisting of methyl α-methoxyisobutyrate, methyl α-formyloxyisobutyrate, methyl α-acetyloxyisobutyrate, and methyl 3-hydroxyisobutyrate, as the solvent (B2).

6. The thinner composition according to claim 4, wherein the solvent (B2) is contained in an amount less than 100% by mass based on the total amount (100% by mass) of the thinner composition.

7. The thinner composition according to claim 4, wherein the solvent (B2) is contained in an amount of 100% by mass or less based on the total amount (100% by mass) of the compound (B1).

8. The thinner composition according to claim 4, wherein the solvent (B2) is contained in an amount less than 112.5% by mass based on the total amount (100% by mass) of the compound (B1).

9. The thinner composition according to claim 4, wherein the solvent (B2) is contained in an amount of 0.0001% by mass or more based on the total amount (100% by mass) of the compound (B1).

10. A method for manufacturing a semiconductor device, comprising:
applying the thinner composition according to claim 1 to a substrate, before applying a photoresist film material or a photoresist underlayer film material to the substrate.

11. A method for manufacturing a semiconductor device, comprising:
applying the thinner composition according to claim 1 to a substrate, after applying a photoresist film material or a photoresist underlayer film material to the substrate and before an exposure.

12. A method for manufacturing a semiconductor device comprising:
forming a photoresist film or a photoresist underlayer film on a substrate, and
removing the photoresist film or the photoresist underlayer film by using the thinner composition according to claim 1.

13. The method for manufacturing the semiconductor device according to claim 12, wherein the photoresist film or the photoresist underlayer film is removed by bringing the thinner composition into contact with an edge and/or a back surface of the substrate on which the photoresist film or the photoresist underlayer film is formed.

14. The method for manufacturing the semiconductor device according to claim 13, wherein the photoresist film or the photoresist underlayer film is removed by spraying the thinner composition to the edge and/or the back surface of the substrate on which the photoresist film or the photoresist underlayer film is formed, while rotating the substrate.

15. The method for manufacturing the semiconductor device according to claim 12, further comprising drying the thinner composition remained on the substrate, after the removing of the photoresist film or the photoresist underlayer film.

16. The method for manufacturing the semiconductor device according to claim 12, further comprising:
soft baking the photoresist film,
partially exposing the soft baked photoresist film to light via a mask, and
developing the exposed photoresist film with a developer to form a photoresist pattern.

17. The method for manufacturing the semiconductor device according to claim 12, wherein in a case where the photoresist film or the photoresist underlayer film is formed on an edge and/or a back surface of the substrate, the method further comprises removing the photoresist film or the photoresist underlayer film on the edge and/or the back surface of the substrate after the photoresist film or the photoresist underlayer film is formed on the substrate.

18. A solvent composition comprising: (B) a solvent comprising (B1) a compound represented by the following general formula (b-1), and (B2) a solvent other than the compound (B1): 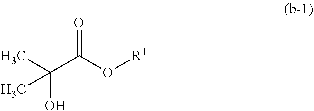
wherein R¹ is an alkyl group having 1 to 10 carbon atoms.

19. The solvent composition according to claim 18, wherein the solvent (B) comprises one or more selected from the group consisting of methyl α-methoxyisobutyrate, methyl α-formyloxyisobutyrate, methyl α-acetyloxyisobutyrate, and methyl 3-hydroxyisobutyrate, as the solvent (B2).

20. The solvent composition according to claim 18, wherein the solvent (B2) is contained in an amount less than 112.5% by mass based on the total amount (100% by mass) of the compound (B1).

21. (canceled)

22. (canceled)

23. (canceled)

24. (canceled)
